(19) United States
(12) Patent Application Publication
(10) Pub. No.: US 2011/0197949 A1
(43) Pub. Date: Aug. 18, 2011

(54) SOLAR COLLECTOR

(76) Inventor: Phillip Gerard Langhorst, Crestwood, MO (US)

(21) Appl. No.: 12/707,063

(22) Filed: Feb. 17, 2010

(51) Int. Cl. H01L 31/042; F24J 2/38; F24J 2/12; H01L 31/02

(52) U.S. Cl. 136/246; 126/605; 126/684; 136/259

(57) ABSTRACT

This invention presents a trough-shaped solar collector. The solar collector includes a trough-shaped reflector for concentrating incoming solar rays upon a focal axis. The reflector includes a flexible reflective membrane having a concave reflective surface. The reflective membrane is braced by a support frame that is inside the concave space created by the reflective surface. The concave reflective surface forms a paraboloidal surface. The reflective membrane is placed in tension and is held against support frame members using clamps.

### CROSS-REFERENCE TO RELATED APPLICATIONS

Not Applicable.

### STATEMENT REGARDING FEDERALLY SPONSORED RESEARCH OR DEVELOPMENT

Not Applicable.

### APPENDIX

Not Applicable.

### FIELD OF THE INVENTION

This invention generally relates to collectors and, more particularly, to a trough-shaped solar collector.

### BACKGROUND OF THE INVENTION

Various solar collectors have been used to capture solar energy for use. Such solar collectors employ reflectors or refractors to concentrate incoming solar rays upon a focal point or focal axis. Solar collectors employing reflectors with parabolic reflective surfaces are usually less expensive and thus economically more attractive than ones with refractors, such as lenses.

Reflectors for solar collectors usually include a reflective material and support structures therefor. Various materials are employed for the reflective material, such as glass, segmented sheets, or molded composite plastic materials. As the size of reflectors has increased to produce significant quantities of energy from solar energy, the weight and size of the reflector structure have also increased. As a consequence, the cost associated with the manufacture of reflectors economically prohibits a large scale adoption of solar collectors.

Many known solar collectors employ longitudinally extending trough-shaped reflectors. The trough-shaped reflectors are of parabolic cross section or configuration. The known trough-shaped reflectors are not only difficult to fabricate, but also require the use of relatively expensive reflective materials and/or heavy support structures. Accordingly, none is economically attractive.

### SUMMARY OF THE INVENTION

The present invention has been made to solve the above-mentioned problems occurring in the prior art, and it is an object of the present invention to provide a solar collector that can be manufactured with light weight and at low cost. It is another object of the present invention to provide a trough-shaped or parabolic-shaped solar collector that can be easily fixed or replaced.

To achieve the above object, in one aspect of the present invention, there is provided a reflector for a solar collector. The reflector includes a reflective member and a support member. The reflective member has a concave reflective surface for reflecting solar rays. The support member braces the reflective member such that the reflective surface is kept concave to form a generally trough or parabolic shape. The support member contacts the concave reflective surface.

In a preferred embodiment of the present invention, the support member includes two end bulkheads. Each of the end bulkheads has a generally parabolic outer contour. The generally parabolic outer contour contacts the concave reflective surface. Additionally, the support member can also include one or more middle bulkheads between the end bulkheads. The middle bulkhead also has a generally parabolic outer contour that contacts the concave reflective surface. Additionally, the support member includes a longitudinally extending spine that connects between the end bulkheads. Preferably, the spine supports the end bulkheads such that the distance between the end bulkheads is kept. Additionally or alternatively, the support member can also include a bracing wire attached between the end bulkheads under tension. Preferably, the bracing wire has a collar or other means to avoid slippage.

In a preferred embodiment, the reflector includes a clamp mechanism which is self-tightening. The self-tightening clamp mechanism can utilize springs for attaching the reflective member to the support member under tension. Preferably, the spring is held in compressed position. The reflector can include a yoke attached to the reflective member. The spring has a yoke receiving portion that can engage with the yoke. Alternatively, the reflector can include a binder clip attached to the reflective member. In this alternative embodiment, the spring has a clip receiving portion for engaging with the binder clip. As an alternative to the spring, flexible cordage such as a bungee cord also can be used.

In a preferred embodiment, the reflective member is a reflective membrane such as flexible film. The reflective member can be made of plastic, aluminum, stainless steel, or steel. The reflective membrane can be made of thin material, the shape of which is kept by tension. Alternatively, the reflective membrane can be made of thicker material which does not wrinkle.

In a preferred embodiment, the support member is made of webs with most material removed.

In a preferred embodiment, the reflector includes a mount on which the support member can be installed. Preferably, the mount includes a first tracking motor and a second tracking motor for driving the support member to rotate toward the sun. Each of the first tracking motor and the second tracking motor has an angle sensor. The first tracking motor and the second tracking motor communicate with each other. Additionally or alternatively, the mount includes a first extension arm and a second extension arm. The support member is fixedly attached to the first and second extension arms. As an alternative to the use of two tracking motors, the reflector can include a single motor for driving the first and second extension arms to rotate such that the first and second extension arms are simultaneously rotated so as not to twist the reflector. Preferably, the mount provides the support member a stored position such that the reflector can be moved between an operating position and a stored position.

In another aspect of the present invention, there is provided a collector including a novel reflector according to the present invention and a receiver. The receiver can be one of various receivers. In a preferred embodiment, the receiver can produce both electric power and heat. In this preferred embodiment, the receiver includes a plurality of photovoltaic cells for absorbing the light and converting the light into electric power. The receiver further has a fluid conduit for collecting heat from the photovoltaic cells.

In an alternative embodiment, the collector according to the present invention can utilize a receiver that simply produces heat only. In this alternative embodiment, the receiver has a light absorbing member for absorbing the light and converting the light into heat. The receiver further has a fluid conduit for collecting heat from the light absorbing member.

In a preferred embodiment, the receiver is a V-shaped receiver. Alternatively, the reflector according to the present invention can be used with a box-shaped receiver. Yet alternatively, the receiver can be an evacuated receiver.

In yet another aspect of the present invention, there is provided a receiver for producing both electric power and heat. The receiver includes a plurality of photovoltaic cells for absorbing light and converting the light into electric power. The receiver also includes a fluid conduit for collecting heat from the plurality of photovoltaic cells.

In a preferred embodiment of the present invention, the receiver further includes a connector strip. The photovoltaic cells are installed on the connector strip in a row. Preferably, the connector strip is punched and wrinkled-raised, and the photovoltaic cells are placed between neighboring wrinkles. Each wrinkle is connected to its respective next photovoltaic cell such that all of the photovoltaic cells are in series.

In a preferred embodiment, the receiver includes two connector strips: a first connector strip and a second connector strip. The photovoltaic cells comprise two rows of photovoltaic cells, each row installed on its respective one of the first and second connector strips. Preferably, the receiver includes a V-shaped base strip having two inner surfaces angled with each other. Each of the first and second connector strips is mounted on one of the two inner surfaces of the V-shaped base strip. Preferably, the receiver further has a cover. The fluid conduit is defined between the cover and the V-shaped base strip such that the fluid conduit extends longitudinally.

The receiver can further have a light-permeable front face member. The front face member is mounted on the base strip such that the front face member protects the plurality of photovoltaic cells. In the embodiment employing a V-shaped base strip, the light-permeable front face member is mounted on the V-shaped base strip such that the front face member covers the inner surfaces. The light-permeable front face member can be made of glass.

Alternatively, the receiver can have a light-permeable tube. The photovoltaic cells and at least part of the fluid conduit are located within the tube. The light-permeable tube can be made of glass. Preferably, the tube is air-evacuated.

In yet another aspect of the present invention, there is provided a receiver that can produce heat. The receiver includes a light absorbing member for absorbing light and converting the light into heat. The receiver also has a fluid conduit for collecting heat from the light absorbing member. The light absorbing member can be made of black metal.

In yet another aspect of the present invention, there is provided a method of manufacturing a receiver. A plurality of photovoltaic cells is installed on a connector strip. The installation is performed by punching and wrinkling the connector strip, and placing the photovoltaic cells on the connector strip such that each of the photovoltaic cells is placed between neighboring wrinkles. The wrinkles of the connector strip can be electrically connected (solder, epoxy) to their respective next photovoltaic cells such that the photovoltaic cells are in series. The connector strip is installed on a base strip such that the connector strip and the base strip is electrically insulated and thermally conducted.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

FIG. 1 is an elevated side view of an embodiment of a solar collector according to the present invention.

FIG. 2A is a perspective view of the support frame of the reflector of the solar collector of FIG. 1.

FIG. 2B is a perspective view of a portion of a bulkhead of the present invention.

FIG. 2C is a larger perspective view of the support frame of FIG. 2A.

FIG. 3 is an enlarged, partial, perspective view of the reflector of the solar collector of FIG. 1 with the spine omitted.

FIG. 4 is an enlarged top view of the spring illustrated in FIG. 3.

FIG. 5 is a perspective view of an embodiment of a solar collector according to the present invention, which is installed on a reflector mount.

FIG. 6 is a perspective view of the solar collector of FIG. 5 in a stored position.

FIG. 7A is a side view of an alternative clamping system that may be used to allow for a rapid change of reflective media.

FIG. 7B is a side view of a second, alternative clamping system that may be used to allow for a rapid change of reflective media.

FIG. 7C is a perspective view of an alternate clamp 80.

FIG. 8A is a perspective view of an embodiment of a receiver with two rows of photovoltaic cells.

FIG. 8B schematically shows how to assemble the receiver of FIG. 8A.

FIG. 8C shows the receiver of FIG. 8A bent into a “V” shape.

FIG. 9A is a front view of an alternate receiver embodiment of the present invention.

FIG. 9 B is a side view of the alternate receiver embodiment of FIG. 9A.

### DETAILED DESCRIPTION OF THE INVENTION

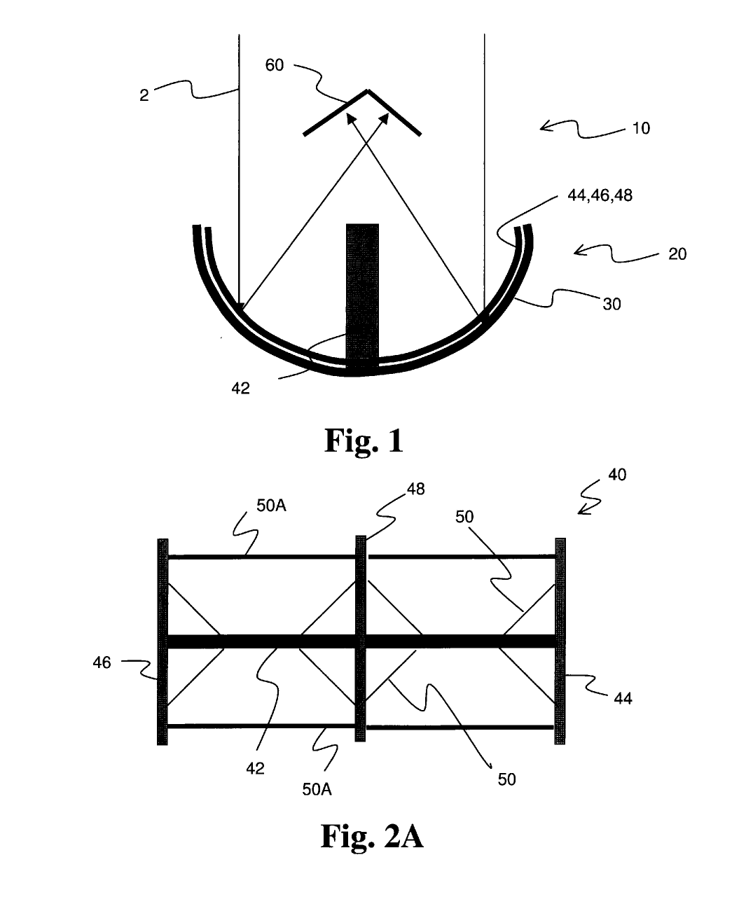

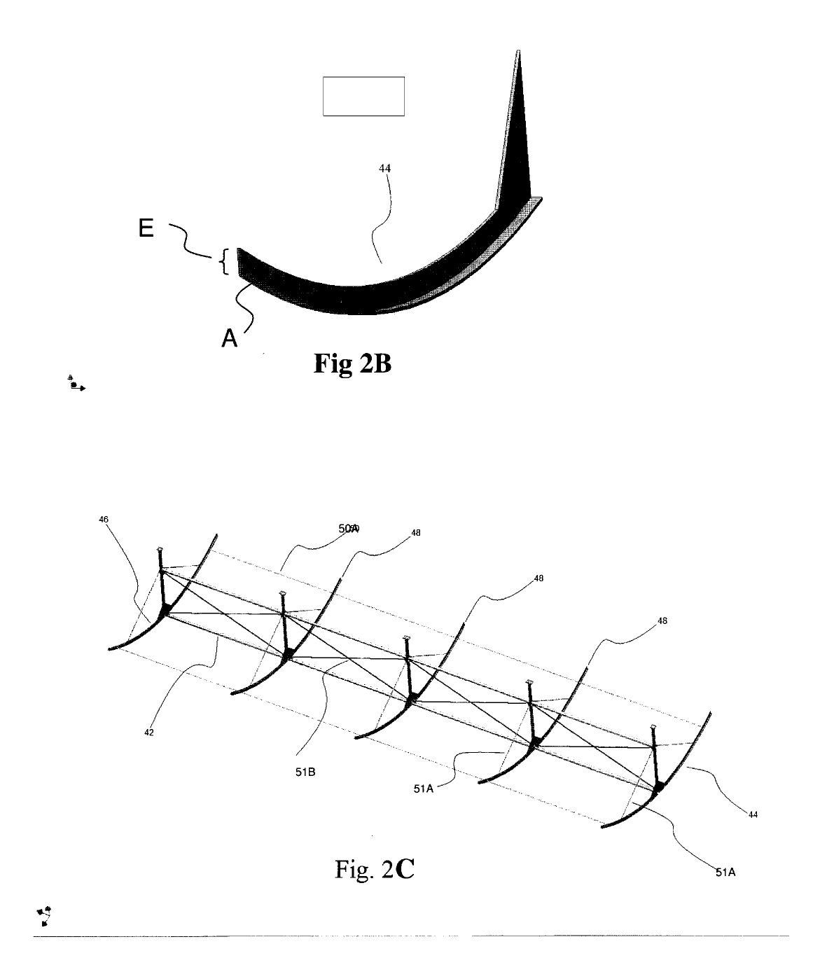

In FIG. 1 there is shown a solar collector 10. The solar collector 10 includes a reflector 20 for concentrating incoming rays 2 upon a focal axis. The reflector 20 extends longitudinally to form a generally trough shape as seen in FIGS. 2A, 2C, 3, 5, and 6. The solar collector 10 also includes a receiver 60 longitudinally extending along the focal axis. The receiver 60 functions to convert the solar energy into electricity and/or heat. The receiver 60 can include solar cells, thermal collector, or both. The reflector 20 includes a reflective membrane 30 braced with a support frame 40. The support frame 40 includes a spine 42 and bulkheads 44, 46, 48.

FIG. 2A shows the support frame 40. The spine 42 extends longitudinally, connecting and supporting the bulkheads 44, 46, 48 such that the distance between neighboring bulkheads can be kept. Each of the end bulkheads 44, 46 and the middle bulkhead 48 has an outer (bottom) contour in a trough or parabolic shape (See FIG. 2B) so that the support frame 40 can have a longitudinally extending trough or paraboloidal outer (bottom) contour. The reflective membrane 30 is kept in constant tension and in contact with the outer (bottom) contour of the support frame 40 so that the reflecting membrane 30 can be kept in a longitudinally-extending trough or paraboloidal shape.

The reflective membrane 30 can be made of flexible material, such as plastic film that is as reflective as a mirror. Preferably, the flexible material is hail-resistant and stiff enough to prevent or reduce wrinkling problems which may deteriorate the solar ray concentrating performance of the reflector 20. The flexible material is also preferably light in weight. One example of membrane material that can make the present invention practical includes polyethylene up to about 0.050″ thick. Another example of a reflective membrane 30 is the use of a reflective film sold under the trade name REFLECTECH® Mirror Film, which reflective film can then be laminated to stiff media such as thin sheets of metal or thin sheets of stiff plastic.

The support frame 40 is made from tubular or flat stock metal and internal wire bracing. The spine 42 and the bulkheads 44, 46, 48 have place for bracing wires 50, 51B or tubes 50A (FIGS. 2A, 2C) to fit and the stock is cut to flex at the point of connection. The bracing wires 50, 51B or tubes 50A longitudinally extend, connecting the bulkheads 44, 46, 48. The bracing wires 50, 51B are installed and stay under tension, while tubes 50A remain rigid. The outer (bottom) contour of the bulkhead 44, 46, 48 together with the bracing tubes 51A keep the reflective membrane 30 in the trough or paraboloidal shape. Spacing between the bulkhead 44, 46, 48 is maintained by both spine 42 and by bracing wires 50, 51B (See FIGS. 2A, 2C). The bracing wires 50, 51B can have collars (not shown) crimped on to avoid slippage relative to the bulkheads 44, 46, 48. The spine 42 and the bulkheads 44, 46, 48 are essentially webs with intervening material removed.

The reflective membrane 30 is attached to the outside of bulkheads 44, 46, 48 by means of a clamp mechanism. In other words, it is critical to the invention that the bulkheads 44, 46 are disposed against the interior surface of reflective membrane 30. It is appreciated that this geometry has a disadvantage of blocking some light. However, it is believed that the device may be made of a longer dimension to compensate for the loss of energy. Moreover, as will be seen below, there are significant advantages in construction, maintenance, and material utilization that have not been appreciated by the prior art. Preferably, the clamp mechanism is self-tightening such that the harder it is pulled, the tighter it grips the membrane 30. Preferably, the self-tightening clamp mechanism can be embodied by utilizing elastic elements such as springs, or flexible cordages like a bungee cord.

As shown in FIG. 2B, the bulkhead 44 portion shown has a radially-extending portion shown generally by E, intersecting an arcuate surface shown generally at A. It is key to the invention that arcuate surface A be disposed on the concave interior side of reflective membrane 30. In this arrangement, it is acknowledged that the radially-extending portion E may block some light. In other words, all of the arcuate surface A of bulkheads 44, 46, 48 contact the concave side of reflective membrane, as opposed to contact with the convex side of reflective membrane 30.

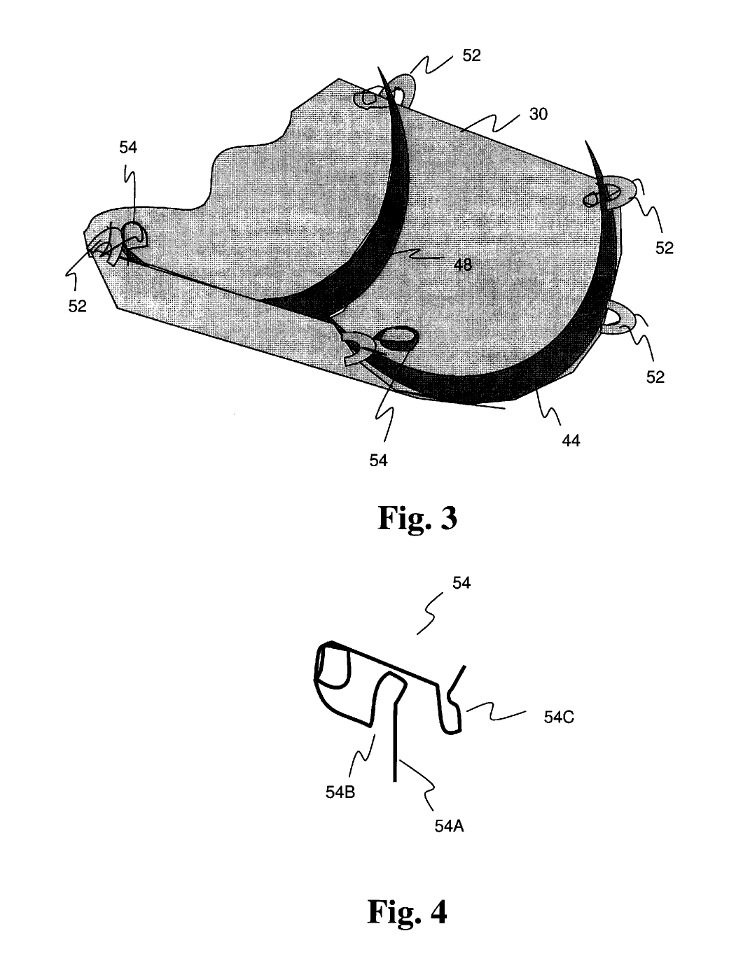

In the exemplary embodiment illustrated in FIGS. 3 and 4, the self-tightening clamp mechanism is embodied by using springs 54. The spring 54 has a stabbing portion 54a that stabs into the bulkheads 44, 46, 48. The spring 54 also has a feature 54b that holds the spring 54 in compressed position. The spring 54 also has a yoke receiving portion 54c that can engage with a small yoke 52. The yokes 52 are attached to the reflective membrane 30 with adhesive or may be welded. Attachment of the reflecting membrane 30 can be done by turning the support frame 40 upside down, rolling the reflective membrane 30 across and attaching the yokes 52 to the springs 54 as reflective membrane 30 is rolled. Once in place, springs 54 are released starting in the center. A kink 54C in the spring 54 holds yoke 52 in place. If the reflective membrane 30 gets damaged for example in a wind storm, it can be easily fix or replaced. Alternatively, binder clips can be used instead of the yokes 52 glued onto the reflecting membrane 30.

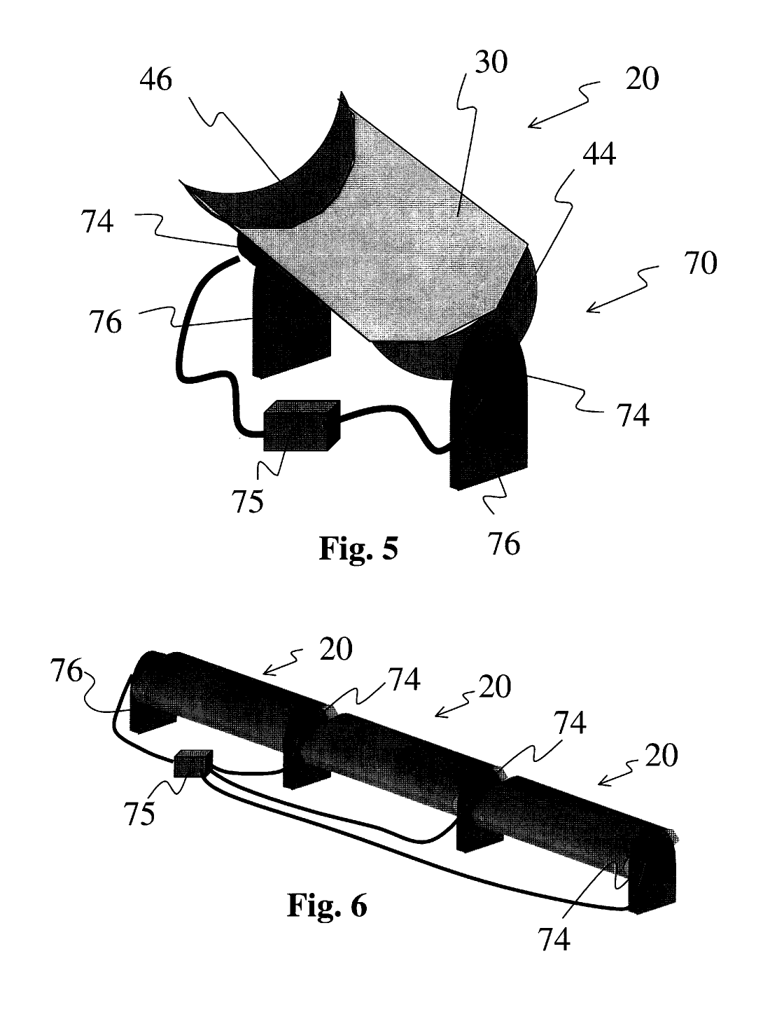

FIGS. 5 and 6 show the reflector 20 installed on a reflector mount 70. The reflector mount 70 has a pair of tracking motors 74, a controller 75 for controlling the tracking motors 74 in order to move them synchronously, and a pair of mount bases 76. The tracking motors 74 are installed in their respective mounting bases 76. The tracking motors 74 drive their respective bulkheads 44, 46 to rotate. The tracking motors 74 on each end function to turn the reflector 20 toward the sun. Each tracking motor 74 has an angle sensor (not shown) and the two tracking motors 74 communicate with each other or with a central controller 75 so as not to twist the reflector 20. Because of this, the reflector 20 does not have to be very stiff torsionally. Because multiple solar collectors 10 may be arranged linearly (in series), it is preferred that the second tracking motor 74 on one unit serve simultaneously as the first tracking motor 74 on the next unit. Therefore, as seen in FIG. 6, the total number of motors required for a linear arrangement of solar collectors is equal to the total number of collector units 10 that are in a particular line plus 1 (one additional motor at the end of each linear series). The profile of bulkhead 44 shown in FIG. 2B has been simplified for clarity in FIGS. 3 and 5. However, it is fully intended that the bulkhead 44 shown in FIGS. 3 and 5 have the same profile as that shown in FIG. 2B.

In addition, extension arms (not shown) would allow additional height so that space underneath can be used. In rain or other inclement weather, the reflector 20 is simply rotated to face the ground to assume a stored position as shown in FIG. 6.

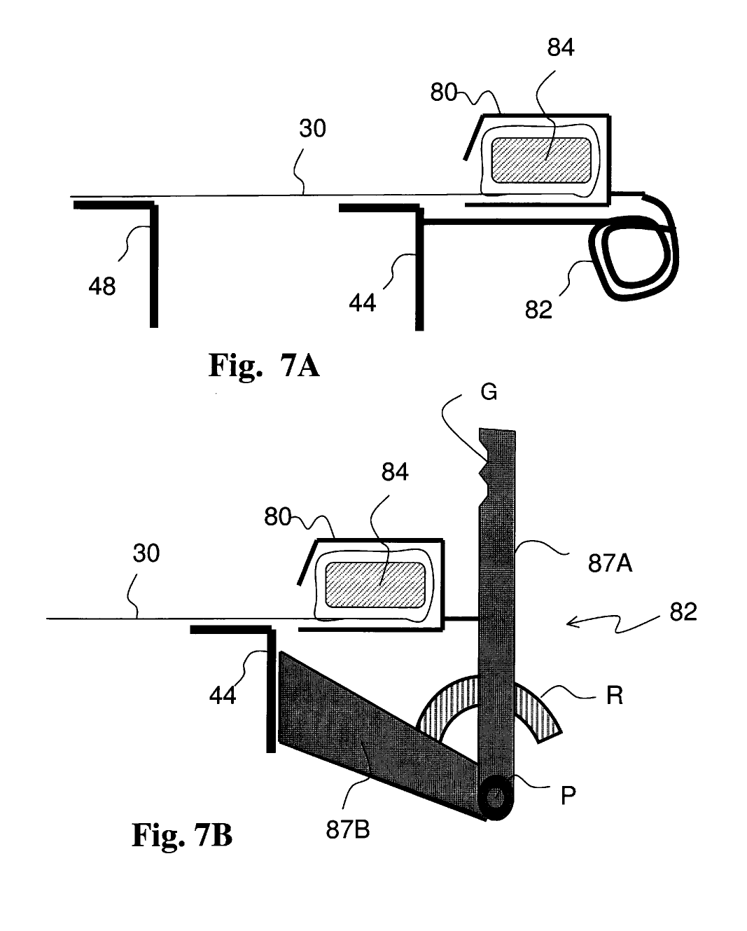

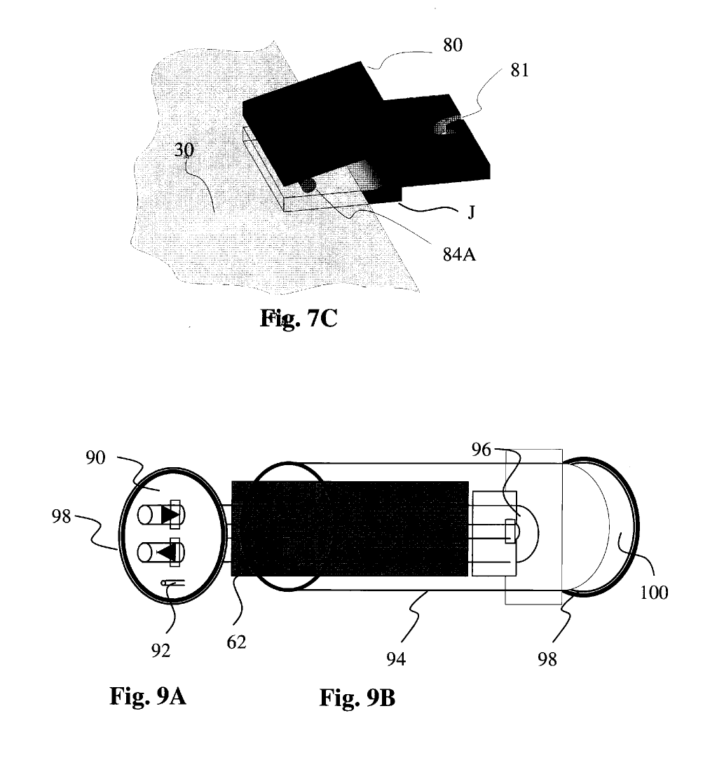

As seen in FIG. 7A, an alternate clamping system is shown. Reflective Membrane is shown generally at 30. Reflective membrane 30 is wrapped at one end around slat 84. Slat 84 provides a surface for gripping reflective membrane 30 and allows for a consistent tension along the width of reflective membrane 30. Slat 84 and an end portion of reflective membrane 30 are gripped by clamp 80. Clamp 80 preferably has an open position for receiving slat 84 and reflective membrane 30, and a closed position for securely gripping slat 84 and reflective membrane 30. Tensioner 82 is any device disposed between a bulkhead 44, 46, 48 and clamp 80 to position clamp 80 relative to a bulkhead 44, 46, 48. Tensioner 82, preferably a spring, is attached between clamp 80 and bulkhead 44. Tensioner 82 may also be an adjustable locking pivot arm, as shown in FIG. 7B. Preferably, tensioner 82 is positioned to apply tension either parallel to or in line with the surface of reflective membrane 30. Tensioner 82 provides consistent tension to reflective membrane 30 to maintain reflective membrane 30 under tension. This clamping system allows for extremely fast replacement of reflective membrane 30. It further permits reflective membrane 30 to experience relatively constant tension despite variations in temperature that may cause expansion and contraction of reflective membrane 30 and or support 40.

In FIG. 7B, reflective member 30 is wrapped around slat 84, which is then surrounded by clamp 80. Clamp 80 is attached to tensioning arm 87A of tensioner, shown generally at 82. Tensioner 82 may comprise a first tensioning arm 87A, having finger grips G, a tensioner bracket 87B, ratchet guide R and pivot pin P. Tensioner bracket 87B is disposed in tension against bulkhead 44, via tensioning arm 87A which pivots about pivot pin P in an arc defined by ratchet guide R. To tension reflective member 30, a user may grip tensioning arm 87 using finger grips G, and pull in a direction away from bulkhead 44. As tensioning arm 87A rotates about pivot pin P along an arc defined by ratchet guide R, tension is placed on reflective member 30, and held at a position by ratchet guide R. It should be appreciated that as tensioning arm 87A rotates, an angled side of clamp 80 contacts reflective member 30 to secure it between slat 84 and claim 84. With this arrangement, it is possible to stretch reflective member 30. To release tension on reflective member 30, a user may grip tensioning arm 87 using finger grips G, and move tensioning arm 87A towards bulkhead 44. As tensioning arm 87A rotates about pivot pin P along an arc defined by ratchet guide R, tension is released on reflective member 30.

In FIG. 7C, clamp 80 is provided with an open angled jaw on one end, and a groove 81 on the other end. A rod 84A is disposed within open angled jaw shown generally at J to provide a friction grip for retaining reflective member 30. When rod 84A is moved to the wider space within open angled jaw J, the friction grip on reflective member 30 is released, to permit maintenance. Groove 81 may receives a male member such as a spring with a kink, such as that shown at C in FIG. 4, attached to a bulkhead 44, 46, 48. It can be appreciated that as the tension on clamp 80 is increased via a spring, rod 84A will rotate against angled surface of J causing increased clamping force on reflective member 30. In other words, tensioner 80 is self-tightening.

Once reflective member 30 is clamped and tightened, the concave reflective surface of reflective member 30 assumes a parabolic shape due to forced contact against the outer parabolic contour of bulkheads 44, 46, 48. It is important to the invention that the reflective member 30 is held in tension by some kind of tensioning device against bulkheads 44, 46, 48, rather like a tent is held in tension, and is not fixed against bulkheads 44, 46, and 48 by screws or other permanent fastener. Therefore, it is theoretically possible for reflective member 30 to slide relative to bulkheads 44, 46, and 48 to accommodate, for example, thermal-related movement.

The reflector 20 according to the present invention can be used with various types of solar receivers. Although the reflector 20 of the present invention can be best used with a novel receiver 60 according to the present invention as described below in details, it can also be advantageously used with various known types of solar receivers. Examples of such known types of solar receivers can include a box-shaped receiver having a box with reflecting internal walls to re-reflect light to one strip of solar cells. Commercially available examples of known types of solar receivers can also include evacuated type of solar receivers. Such known receivers are not explained in details in this application.

A receiver 60 according to the present invention can use solar cells, thermal collector, or both.

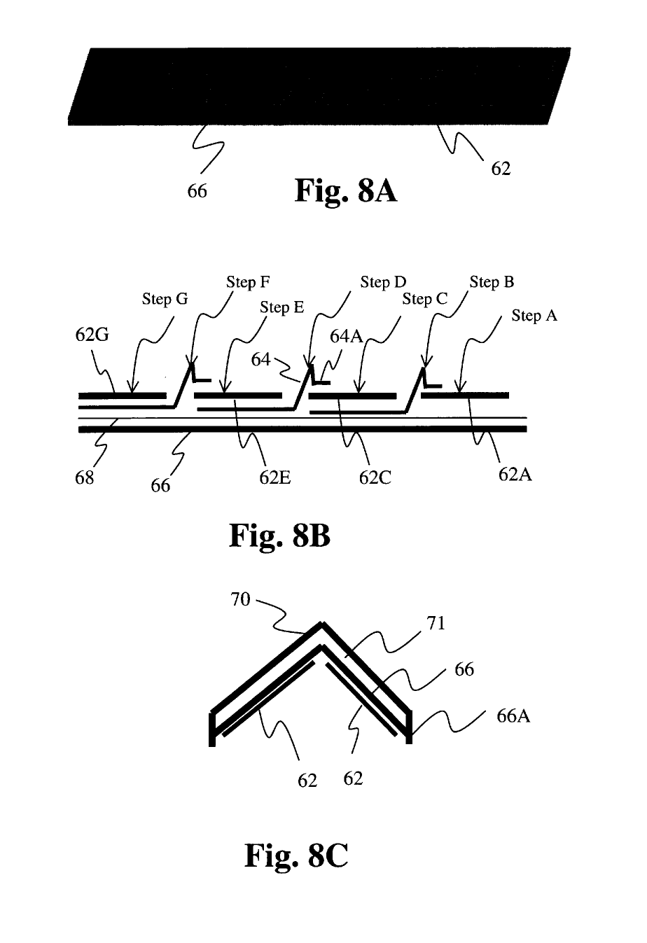

In the embodiment illustrated in FIGS. 8A, 8B, and 8C, the receiver 60 includes two rows of photovoltaic cells 62. Alternatively, a single row of photovoltaic cells 62 can also be employed. Yet alternatively, three or more rows of photovoltaic cells 62 can also be employed. Each of the rows of photovoltaic cells 62 are installed on a connector strip 64. Although the connector strip 64 can be made of copper, tin plated steel or some type of foil can be preferred because of cost consideration.

First, the connector strip 64 is punched and wrinkled-raised as best seen in FIG. 8B. According to Step A, a first photovoltaic cell 62A is placed on adhesive 68 which is layered above base strip 66. Then, according to Step B, connector strip 64 is placed on adhesive 68. At the same time, electrically-conductive epoxy (not shown) is applied to the underside of 64A so that as connector strip 64 is placed on adhesive 68 in Step B, the underside of wrinkle 64A is placed in electrical contact or electrical communication with the top of first photovoltaic cell 62A. Next, according to Step C, an electrically-conductive epoxy (not shown) is applied to the underside of second photovoltaic cell 64C, and then second photovoltaic cell is placed on the connector strip 64 that was applied in Step B. Next, according to Step D, electrically-conductive epoxy (not shown) is applied to the underside of 64A so that as connector strip 64 is placed on adhesive 68 in Step D, the underside of wrinkle 64A is placed in electrical contact or electrical communication with the top of second photovoltaic cell 62C. Then, according to Step E, an electrically-conductive epoxy (not shown) is applied to the underside of third photovoltaic cell 64E, and then third photovoltaic cell 64E is placed on the connector strip 64 that was applied in Step D. Next, according to Step F, electrically-conductive epoxy (not shown) is applied to the underside of 64A so that as connector strip 64 is placed on adhesive 68, the underside of wrinkle 64A is placed in electrical contact or electrical communication with the top of third photovoltaic cell 62E. Then, according to Step G, an electrically-conductive epoxy is applied to the underside of fourth photovoltaic cell 64G, and then fourth photovoltaic cell 64G is placed on the connector strip 64 that was applied in Step F. The photovoltaic cells 62 are adhered for high thermal and electrical conductivity.

As best seen in FIG. 8B, the wrinkles 64a of the connector strip 64 are cut, bent, and soldered or epoxied to their respective next cells 62 so that all photovoltaic cells can be in series.

In the illustrated embodiment, two connector strips 64, each having a row of photovoltaic cells 62 installed thereon, are placed on a base strip 66. The base strip 66 is preferably thermally conductive. The two connector strips 64 are attached to the base strip 66 with adhesive 68. The adhesive 68 is preferably electrically insulating but thermally conducting. It may be possible to perform the installation of the two connector strips 64 on the base strip 66 at the same time with the installation of the two rows of photovoltaic cells 62 on the two connector strips 64.

In the embodiment as illustrated in FIG. 8C, the base strip 66 is bent into “V” shape with a longitudinally extending flange 66A at each lateral end. The advantages of this “V” shape configuration includes that light not absorbed in one side can be reflected toward the other side and there get absorbed, whereby increasing the overall absorption efficiency.

A V-shaped cover 70 is soldered on to the flanges 66A to form a water jacket 71 between the cover 70 and the base strip 66. Fluid, typically water, can flow through the water jacket to cool the photovoltaic cells 62. Accordingly, the receiver 60 can produce electricity as well as hot water.

The receiver 60 can have a semicircular front (not shown) made of glass to exclude dirt. Alternatively, the receiver 60 can be installed into a glass tube (not shown). The glass tube can also be evacuated so as to cut down on heat losses.

As an alternative to photovoltaic cells 62, other types of energy converting members can be used, such as black metal for simply absorbing heat.

In FIGS. 9A and 9B, an alternate embodiment of a receiver 60 is provided. In particular, front plate 90 is provided with vacuum port 92 for evacuating the receiver. O-ring 98 provides a seal between front plate 90 and glass tube 94. Similarly, o-ring 98 provides a seal between back plate 100 and glass tube 94. Disposed within glass tube 94, light receiver plates 62 are in thermal communication with copper tube 96. Copper tube 96 is adapted for the flow of liquid, preferably water. The receiver shown in FIGS. 9A and 9B may be used in lieu of the receiver shown in FIGS. 8A-8C.

As various modifications could be made to the exemplary embodiments, as described above with reference to the corresponding illustrations, without departing from the scope of the invention, it is intended that all matter contained in the foregoing description and shown in the accompanying drawings shall be interpreted as illustrative rather than limiting. Thus, the breadth and scope of the present invention should not be limited by any of the above-described exemplary embodiments, but should be defined only in accordance with the following aims appended hereto and their equivalents.

What is claimed is:

1. A reflector for a solar collector, comprising:
a reflective member having a concave and parabolic reflective surface for reflecting light; and
a support member having a longitudinally-extending spine, two end bulkheads connected to said spine, said support member for bracing said reflective member such that said reflective surface is kept concave to form a generally trough shape; and
wherein each of said end bulkheads has a generally parabolic outer contour contacting said concave reflective surface.

2. The reflector of claim 1, further comprising:
a tensioning device attached to said bulkheads and to said reflective member for holding said reflective member in tension against said bulkheads.

3. The reflector of claim 2, wherein said tensioning device comprises a plurality of clamps.

4. The reflector of claim 1, wherein said support member further comprises a middle bulkhead between said end bulkheads, said middle bulkhead having a generally parabolic outer contour, said generally parabolic outer contour contacting said concave reflective surface.

5. The reflector of claim 4, wherein said support member further comprises a bracing wire under tension attached between said spine and one of said end bulkheads and said middle bulkhead.

6. The reflector of claim 1, further comprising:
a first tracking motor for driving and rotating said support member;
a second tracking motor for driving said rotating said support member, wherein each of said first tracking motor and said second tracking motor has an angle sensor; and
a controller in communication with said first tracking motor and said second tracking motor.

7. The reflector of claim 6, further comprising:
a mount;
wherein said support member is pivotally attached to said mount; and
wherein a shaft of said first and second tracking motors serves as a pivot for said support member.

8. The reflector of claim 6, further wherein said controller for rotates said end bulkheads synchronously.

9. A collector comprising:
a receiver;
a reflective member having a concave reflective surface for reflecting light; and
a support member having a longitudinally-extending spine, two end bulkheads connected to said spine, said support member for bracing said reflective member such that said reflective surface is kept concave to form a generally trough shape; and
wherein each of said end bulkheads has a generally parabolic outer contour contacting said concave reflective surface; and
wherein said receiver is disposed at the focus of said concave reflective surface.

10. The collector of claim 9, further comprising:
a tensioning device attached to said bulkheads and to said reflective member for holding said reflective member in tension against said bulkheads.

11. The reflector of claim 10, wherein said tensioning device comprises a plurality of clamps.

12. The collector of claim 9, wherein said receiver produces both electric power and heat.

13. The collector of claim 9, wherein said receiver comprises:
a photovoltaic cell for absorbing the light and converting the light into electric power; and
a fluid conduit for collecting heat from said photovoltaic cell.

14. The collector of claim 9, wherein said receiver further comprises a tube, wherein said photovoltaic cell is disposed within said tube.

15. The collector of claim 9, wherein said receiver comprises:
a light-absorbing member for absorbing the light and converting the light into heat;
a fluid conduit for collecting heat from said light absorbing member.

16. The collector of claim 15, further comprising:
a tube, wherein said light-absorbing member is disposed within said tube.

17. A receiver for producing both electric power and heat, comprising:
a plurality of photovoltaic cells for absorbing light and converting the light into electric power; and
a fluid conduit for collecting heat from said plurality of photovoltaic cells.

18. The receiver of claim 17, further comprising a connector strip, wherein said photovoltaic cells are installed on said connector strip in a row.

19. The receiver of claim 17, further comprising a light-permeable front face member, wherein said front face member is mounted on said V-shaped base strip such that said front face member covers said inner surfaces.

20. The receiver of claim 17, further comprising an evacuated light-permeable tube, wherein said plurality of photovoltaic cells and at least part of said fluid conduit are located within said tube.

21. A method of manufacturing a receiver, comprising steps of:
preparing a connector strip;
installing a plurality of photovoltaic cells on said connector strip;
wherein said step of installing comprises punching said connector strip, wrinkling said connector strip, and placing said plurality of photovoltaic cells on said connector strip such that each of said photovoltaic cells is placed between neighboring wrinkles, electrically connecting said wrinkles of said connector strip to their respective next photovoltaic cells such that said photovoltaic cells are in series; and
installing said connector strip on a base strip such that said connector strip and said base strip is electrically insulated and thermally conducted.
